(19) United States
(12) Patent Application Publication
(10) Pub. No.: US 2026/0118458 A1
(43) Pub. Date: Apr. 30, 2026

(54) METHODS AND SYSTEMS TO REDUCE MAGNETIC RESONANCE IMAGING SENSITIVITY TO MAGNETIC FIELD INHOMOGENEITIES

(71) Applicant: THE REGENTS OF THE UNIVERSITY OF CALIFORNIA, Oakland, CA (US)

(72) Inventors: Divya S. Bolar, San Diego, CA (US); Eric C. Wong, Del Mar, CA (US); Thomas Liu, San Diego, CA (US)

(21) Appl. No.: 18/927,763

(22) Filed: Oct. 25, 2024

(51) Int. Cl. G01R 33/46; G01R 33/56; G01R 33/563; G01R 33/565

(52) U.S. Cl. CPC G01R 33/4616; G01R 33/5608; G01R 33/56366; G01R 33/56563

(57) ABSTRACT

Methods, systems, and apparatus for magnetic resonance imaging (MRI) using an adiabatic magnetic pulse train are disclosed. In some aspects, a method for magnetic resonance imaging includes: applying at a first time, to a subject located in a magnetic field, a first adiabatic magnetic pulse train comprising excitation pulses and adiabatic refocusing pairs; obtaining a first MRI image comprising first MRI data acquired after the applying of the first adiabatic magnetic pulse train to the subject at the first time; applying a second adiabatic magnetic pulse train comprising excitation pulses and adiabatic refocusing pairs to the subject at a second time while the subject is located in the magnetic field; obtaining a second MRI image comprising second MRI data acquired after the applying of the second adiabatic magnetic pulse train to the subject at the second time; acquiring third MRI data corresponding to blood flow in the subject based on differences between the first MRI image and the second MRI image; and obtaining an MRI perfusion image based on the third MRI data that excludes some or all MRI artifacts arising from regions of inhomogeneity in the magnetic field.

### TECHNICAL FIELD

This patent document relates to magnetic resonance image (MRI) technologies.

### BACKGROUND

Imaging through MRI techniques is well known and has been widely applied in imaging applications in medical, biological and other fields. In general, a typical MRI technique produces an image of a selected body part of an object under examination by manipulating the magnetic spins in a body part and processing measured responses from the magnetic spins. A MRI system may include hardware to generate different magnetic fields for imaging, including a static magnetic field along a z-direction to polarize the magnetic spins, gradient fields along mutually orthogonal x, y, or z directions to spatially select a body part for imaging, and an RF magnetic field to manipulate the spins.

### SUMMARY

Disclosed herein are methods, systems, and devices for magnetic resonance imaging using an adiabatic magnetic pulse train.

In one aspect, a method for magnetic resonance imaging is provided. The method comprises: applying at a first time, to a subject located in a magnetic field, a first adiabatic magnetic pulse train comprising excitation pulses and adiabatic refocusing pairs; obtaining a first MRI image comprising first MRI data acquired after the applying of the first adiabatic magnetic pulse train to the subject at the first time; applying a second adiabatic magnetic pulse train comprising excitation pulses and adiabatic refocusing pairs to the subject at a second time while the subject is located in the magnetic field; obtaining a second MRI image comprising second MRI data acquired after the applying of the second adiabatic magnetic pulse train to the subject at the second time; acquiring third MRI data corresponding to blood flow in the subject based on differences between the first MRI image and the second MRI image; and obtaining an MRI perfusion image based on the third MRI data that excludes some or all MRI artifacts arising from regions of inhomogeneity in the magnetic field. In some implementations, at least one of the first adiabatic magnetic pulse train or the second adiabatic magnetic pulse train further comprises gradient pulses. In some implementations, at least one of the first MRI image or the second MRI image is obtained in-part based on selective interaction of the first adiabatic magnetic pulse train or the second adiabatic magnetic pulse train with spins in arterial blood water of the subject based on a velocity of the arterial blood water being at or above a predetermined threshold velocity.

In another aspect, a computer program product, embodied on a computer-readable medium, operable to cause a data processing apparatus to perform operations for magnetic resonance imaging is provided. The operations comprise: applying at a first time, to a subject located in a magnetic field, a first adiabatic magnetic pulse train comprising excitation pulses and adiabatic refocusing pairs; obtaining a first MRI image comprising first MRI data acquired after the applying of the first adiabatic magnetic pulse train to the subject at the first time; applying a second adiabatic magnetic pulse train comprising excitation pulses and adiabatic refocusing pairs to the subject at a second time while the subject is located in the magnetic field; obtaining a second MRI image comprising second MRI data acquired after the applying of the second adiabatic magnetic pulse train to the subject at the second time; acquiring third MRI data corresponding to blood flow in the subject based on differences between the first MRI image and the second MRI image; and obtaining an MRI perfusion image based on the third MRI data that excludes some or all MRI artifacts arising from regions of inhomogeneity in the magnetic field. In some implementations, at least one of the first adiabatic magnetic pulse train or the second adiabatic magnetic pulse train further comprises gradient pulses. In some implementations, at least one of the first MRI image or the second MRI image is obtained in-part based on selective interaction of the first adiabatic magnetic pulse train or the second adiabatic magnetic pulse train with spins in arterial blood water of the subject based on a velocity of the arterial blood water being at or above a predetermined threshold velocity.

In another aspect, a magnetic resonance imaging system is provided. The system comprises: a radio frequency (RF) subsystem configured to: apply at a first time, to a subject located in a magnetic field, a first adiabatic magnetic pulse train comprising excitation pulses and adiabatic refocusing pairs, and apply at second time, to the subject while located in the magnetic field, a second adiabatic magnetic pulse train comprising excitation pulses and adiabatic refocusing pairs; and a processor and a computer-readable medium with instructions stored thereon. In some implementations, at least one of the first adiabatic magnetic pulse train or the second adiabatic magnetic pulse train further comprises gradient pulses. In some implementations, at least one of the first MRI image or the second MRI image is obtained in-part based on selective interaction of the first adiabatic magnetic pulse train or the second adiabatic magnetic pulse train with spins in arterial blood water of the subject based on a velocity of the arterial blood water being at or above a predetermined threshold velocity.

In some implementations, the instructions upon execution by the processor cause the processor to: obtain a first MRI image comprising first MRI data acquired after the applying of the first adiabatic magnetic pulse train to the subject at the first time; obtain a second MRI image comprising second MRI data acquired after the applying of the second adiabatic magnetic pulse train to the subject at the second time; acquire third MRI data corresponding to blood flow in the subject based on differences between the first MRI image and the second MRI image; and obtain an MRI perfusion image based on the third MRI data that excludes some or all MRI artifacts arising from regions of inhomogeneity in the magnetic field.

In yet another aspect, the above-described methods are embodied in the form of processor-executable code and stored in a computer-readable program medium. The processor-executable code included in the computer-readable program medium when executed by a processor, causes the processor to implement the methods described in this patent document.

In yet another exemplary embodiment, a device that is configured or operable to perform the above-described methods is disclosed.

The above and other aspects and their implementations are described in greater detail in the drawings, the descriptions, and the claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIGS. 1A-B show an example of an adiabatic magnetic pulse train based on the disclosed technology (FIG. 1A) and a composite refocusing train (FIG. 1B) as a reference.

FIG. 2 shows an example of relative cerebral blood flow (CBF) maps and associated temporal signal-to-noise ratio (tSNR) maps based on the disclosed technology.

FIGS. 3A-D show example velocity responses to an adiabatic magnetic pulse train based on the disclosed technology (FIGS. 3A-B) and a composite refocusing train (FIGS. 3C-D) as a reference.

FIGS. 4A-D show example color maps of velocity profiles of an adiabatic magnetic pulse train based on the disclosed technology (FIGS. 4A-B) and a composite refocusing train as a reference (FIGS. 4C-D).

FIG. 5 shows example plots of normalized magnetization difference after subtraction (ΔM/M₀) based on the disclosed technology

FIG. 6 shows example perfusion maps and corresponding magnetic field maps based on the disclosed technology.

FIG. 7 shows example perfusion maps and corresponding magnetic field maps based on the disclosed technology.

FIG. 8 shows example gray-matter spatial coefficient of variation data based on the disclosed technology.

FIG. 9 shows example label-control difference images and corresponding magnetic field maps based on the disclosed technology.

FIG. 10 shows an example flow diagram illustrating a method based on the disclosed technology.

### DETAILED DESCRIPTION

Velocity-selective arterial spin labeling (VS-ASL) is a non-invasive MRI method commonly used to measure cerebral blood flow (CBF) in a subject. State-of-the-art VS-ASL approaches use so-called velocity-selective inversion (VSI) to create a magnetic “label” in arterial blood, which is then delivered to the cerebral microvasculature. MR imaging of this label allows generation of CBF images. The standard VSI train in the MRI pulse sequence uses a series of composite radiofrequency pulses to refocus magnetization in between excitation pulses. These composite pulses are mandatory to reduce the marked sensitivity of the VSI pulse train to imperfections of the static magnetic field (B₀) and the transmit magnetic field (B₁⁺). Despite this, significant sensitivity issues persist, leading to prominent artifacts in the final CBF images.

Described herein are example embodiments that, among other features and benefits, reduce sensitivity of MRI VSI pulse trains to B₀/B₁⁺ inhomogeneity using adiabatic refocusing pulses. The technical solutions described in the present document can be embodied in implementations to improve MRI images, among other features. In some example embodiments, adiabatic pulses (e.g., hyperbolic secant pulses) are used to perform refocusing, and at the same time reduce the length of the pulse train and the amount of unwanted T2 signal decay. The disclosed techniques can result in dramatically improved performance in simulation, phantom data, and human CBF data. For example, artifacts in the CBF maps seen when using the standard composite refocusing approach are completely eliminated by the disclosed adiabatic refocusing approach. In some example embodiments, an adiabatic magnetic pulse train based on the disclosed technology can be used for dynamic and static magnetic resonance (MR) angiography. The disclosed embodiments, among other features and benefits, can be implemented to improve image quality in various MR applications.

As mentioned above, existing VSI pulse trains use composite refocusing pulses. The disclosed embodiments use adiabatic refocusing pulses to dramatically improve performance of the pulse train. Adiabatic refocusing has yet to be used for VSI, which offers much higher signal-to-noise ratio (SNR) compared to other techniques such as velocity-selective saturation (VSS) approaches. Therefore, VSI trains are expected to become the default train for clinical translation of VS-ASL. VS-ASL is an MRI technique which can be used to create images of brain blood flow and is promising for the study of many brain diseases. However, the technique is prone to errors in the images to due technical factors, reducing the method's utility, efficacy, and accuracy. The example embodiments described in the present document offer a new way to improve these brain blood flow images and eliminate these errors, making it more useful for patients undergoing MR imaging of their brain.

The disclosed embodiments include a VS-ASL labeling train that uses adiabatic refocusing pulses for velocity selective inversion. The adiabatic refocusing pulses can enhance performance by reducing artifacts and signal loss that result from B₀/B₁⁺ inhomogeneity. The ability to create perfusion images with minimal artifact via a single label-control subtraction adds inherent robustness that can facilitate clinical translation.

This patent document describes exemplary MRI imaging techniques in the context of CBF imaging in a human subject for ease of description. The exemplary MRI imaging techniques could be employed for imaging other body parts and structures.

To facilitate understanding of the present application, a general discussion of VS-ASL MRI imaging techniques is provided. One MRI imaging strategy for imaging tissue of a subject is to implement a velocity-selective ASL sequence comprising two parts: (i) label image acquisition and (ii) control image acquisition. During label image acquisition, a label image is obtained by applying a first magnetic pulse to the subject that magnetically “labels” spins in the blood of the subject based on their velocity. During control image acquisition, a second magnetic pulse is applied to the subject and a control image is obtained. The label image contains first static tissue information of the subject as well as velocity-dependent information associated with the magnetically labeled spins, while the control image contains second static tissue information of the subject without velocity-dependent information. The control image and the label image obtained during the ASL sequence form a control-label pair. By performing signal subtraction between the control and label images, an MRI perfusion image can be obtained.

VS-ASL labels blood based on velocity rather than spatial position. This results in the rapid delivery of the label to the microvasculature (when appropriate imaging parameters are chosen), allowing accurate cerebral blood flow measurement in the presence of arterial transit delays. VS-ASL has proven effective for imaging perfusion including in patients with prolonged arterial transit times due to steno-occlusive disease and brain tumor, providing accurate CBF measurements where conventional spatial-based arterial spin labeling (ASL) approaches have failed.

Despite compelling findings, VS-ASL has yet to achieve the same clinical use as spatial-based pseudocontinuous ASL. One reason is that early VS-ASL implementations used VSS for label generation, resulting in significantly lower SNR compared to inversion-based pseudocontinuous ASL. Within the past decade, however, VSI approaches have been introduced and considerably increase SNR relative to VSS. So-called Fourier-transform VSI (FT-VSI) uses excitation velocity k-space formalism to perform velocity-dependent inversion by interleaving RF excitation pulses with velocity-encoded gradients. Such approaches, however, are prone to errors related to inhomogeneity in B₀ and B₁⁺ magnetic fields, which can result in substantial artifacts and subsequent errors in CBF measurement. FT-VSI trains have subsequently undergone several refinements to reduce B₀/B₁⁺ sensitivity, with the latest designs inserting paired composite refocusing pulses (with Malcom-Levitt (MLEV)-16 phase cycling) between the excitation pulses. For the labeling module, this RF pulse arrangement is coupled with repeating bipolar gradient pairs for velocity encoding. For the control module, two general options are possible: (i) a “velocity-insensitive” control (VIC), which disables the gradients entirely, and (ii) a “velocity-compensated” control (VCC), which uses unipolar gradients.

However, the MLEV-16 paired composite refocusing approach remains vulnerable to B₀/B₁⁺ imperfections via (i) high spatial frequency “stripe artifacts” (prominently seen in velocity-selective MRA) and (ii) non-zero DC subtraction components (DC bias), particularly when using a VIC. In VS-ASL, these phenomena can manifest as spatially dependent label-control subtraction errors in static tissue, resulting in pronounced artifacts and signal dropout. To mitigate these errors, a clever dynamic phase-cycling (DPC) approach was introduced, which modulates the phase of the refocusing pulses by adding 90 every label-control pair for a total of four dynamic phases (0°, 90°, 180°, and 270°). Averaging the label-control subtraction images across the four dynamic phases theoretically and empirically removes stripe and DC bias artifacts across a broad B₀/B₁⁺ range. Using a VCC can reduce these static tissue artifacts without requiring the use of DPC, although the improvement is less pronounced compared to using a VIC with DPC. Furthermore, VCC results in degraded velocity-selective (VS) profiles, reduced labeling efficiencies, and worsened eddy current artifacts, although there is better matching of label/control diffusion attenuation. For single-shot read-outs, DPC generates one perfusion image for every four label-control pairs (or every eight TRs), as opposed to every single label-control pair (or two TRs) in typical ASL.

Despite the innovations offered by DPC, the eight-TR requirement poses a significant limitation for applications that require high temporal resolution such as perfusion-based functional MRI (fMRI) and microvascular pulsatility. Furthermore, there is increased susceptibility to physiologic and bulk motion artifacts due to averaging over eight TRs. Additionally, ASL data-censoring approaches are less effective, as outlier detection can only be performed on one dynamic-phase series at a time.

In one example implementation, the disclosed embodiments can be used to improve an FT-VSI train's robustness to B₀/B₁⁺ inhomogeneity for a single label-control pair when using a VIC, obviating the need for dynamic phase cycling and avoiding its associated limitations.

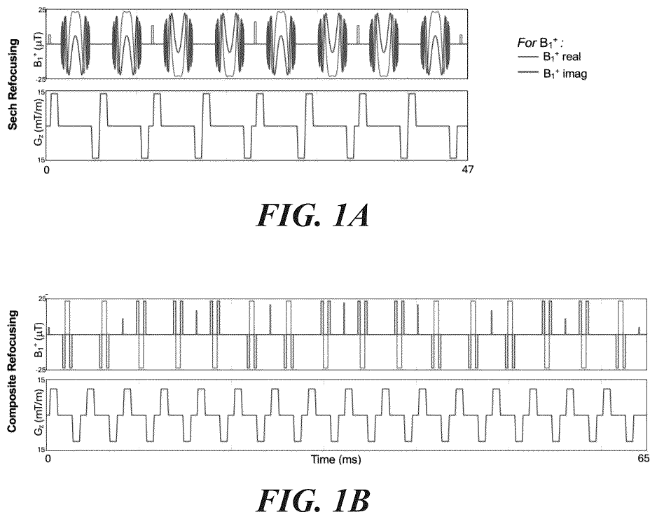

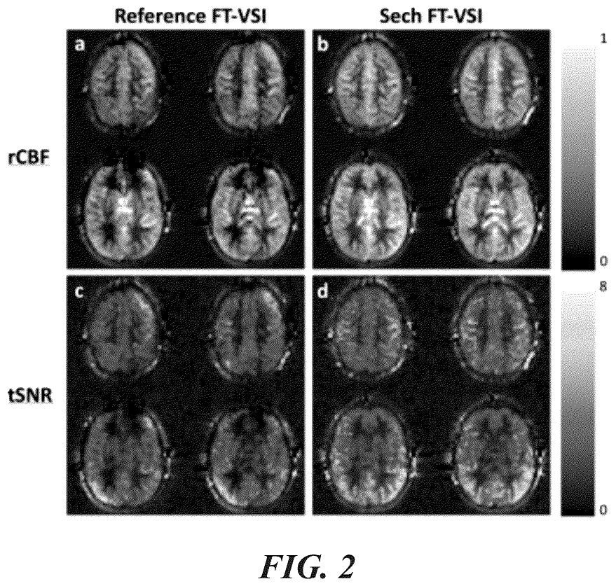

FIG. 1 shows an example of an adiabatic magnetic pulse train based on the disclosed technology (FIG. 1A) and a composite refocusing train (FIG. 1B) as a reference. The example 47-ms VSI train of FIG. 1A comprises five sinc-modulated hard excitation pulses interleaved with four adiabatic hyperbolic secant (sech) refocusing pairs (e.g., μ=5, β=400; n=0.2 for cosine envelope; 3.142 ms) modulated by MLEV-8 phase cycling. In this example, the sech pulse uses variable-rate selective excitation to minimize pulse duration. As shown in FIG. 1B, the reference composite refocusing train is a conventional 64-ms FT-VSI train which has been previously used in several VS-ASL investigations. The reference train comprises nine sinc-modulated hard excitation pulses and eight composite (90°ₓ-180°_{y}-90°ₓ; 1 ms) refocusing pairs modulated by MLEV-16 phase cycling. Both reference and sech trains can be implemented into a VS-ASL preparation module (e.g., velocity cutoff (V_{cut})=2 cm/s, Tₛₐₜ=1500 ms, τ/T₁/T=500/1000/735 ms, T_{R}=3000 ms, 64 meas, scan time ˜3:20) using, for example, a 3D gradient and spin echo (GRASE) readout (e.g., voxel size=4×4×6 mm³, 40 slices, single-shot, TE=15.42 ms, GRAPPA acceleration 2×2 in PExSlice) on an MRI scanner. FIG. 2 shows examples of relative CBF maps (FIG. 2A-B) and associated tSNR maps (FIG. 2C-D) for a human subject acquired using a reference (left) and sech FT-VSI train (right) in a human subject.

In some implementations, the pulse trains described above (i.e., the adiabatic magnetic pulse train and composite refocusing train shown in FIGS. 1A-B) can be used to collect VS-ASL data. In one example study, these pulse trains were used to collect VS-AL data on 1) an agarose phantom and 2) five healthy human subjects (4 males, 1 female, ages 24-47) scanned on the same MRI scanner. VS-ASL data using both pulse trains with and without DPC was collected on the agarose phantom (16 measurements, scan time=1:25, see subsequent section for VS-ASL parameters) along with B₀ and B₁⁺ field maps using an MRI scanner with a 32-channel head coil. Pairwise label-control subtraction was performed on the time-series data and then averaged to create mean subtraction maps. V_{cut} of the labeling trains depicted in FIGS. 1A and 1B was set to 2 cm/s based on the gradient trains (sech: Gₘₐₓ=13.9 mT/m, gradient lobe duration=900 μs, slope of gradient ramp=139 T/m/s; composite: Gₘₐₓ=11.1 mT/m, gradient lobe duration=900 μs, slope of gradient ramp=111 T/m/s). For the reference train of FIG. 1B, the gradient pulses were turned off. In this example study, a VIC approach was chosen due to its superior VS profiles and labeling efficiency across a wide B₀/B₁⁺ range and reduced eddy current artifacts, relative to the VCC. The conventional composite refocusing pulses were replaced with adiabatic refocusing pulses as shown in FIG. 1A, which are less sensitive to variations in B₀ and B₁⁺ and have been used successfully in VS saturation approaches.

The amplitude A (t) and frequency modulation w (t) functions for the adiabatic hyperbolic secant pulse of FIG. 1A are given as follows:

$$A ( t ) = sech ( β t )$$

$$ω ( t ) = - μβtan h ( β t )$$

where μ=5 and β=400 for the example study. This pulse was transformed into a pulse of the form cosⁿ(t) on the interval −π/2<t<π/2 using variable-rate selective excitation, with n as a tunable parameter that allows the pulse to approach a rectangular shape as n approaches 0. For the pulse used in this study (FIG. 1A), n=0.2.

In the example study presently described, the human scanning and data analysis protocol comprised the following:
(i) B₀ field mapping using a dual echo spoiled gradient-echo service sequence (voxel size=4×4×6 mm³, FOV=256×256×144 mm³, 24 slices, flip angle=60°, TE₁/TE₂/TR=4.92/7.38/400 ms, scan time=0:54).
(ii) B₁⁺ field mapping using a presaturation-based B₁ mapping approach with a turbo FLASH read-out (flip angle of presaturation pulse=80°, flip angle of turbo FLASH excitation pulses=8°, delay between presaturation pulse and turbo FLASH read-out=4 ms, voxel size=4×4×5 mm³, FOV=256×256×144 mm³, 24 slices, 1-mm gap between slices, TE/TR=1.97/6550 ms, and scan time=0:13).
(iii) Double inversion-recovery (DIR) sequence to null white matter and CSF for gray-matter (GM) masks (TI₁=3100 ms and TI₂=475 ms) using a single-shot 3D GRASE readout (voxel size=3.5×3.5×5 mm³, FOV=224×224×160 mm³, 32 slices, TE=12 ms, EPI factor=15, turbo spin echo factor=16, readout duration for each EPI module=8 ms, total readout duration=220 ms, bandwidth=2604 Hz/pixel, T_{R}=4600 ms, parallel acquisition technique acceleration=3×2 in PExSlice [GRAPPA], one measurement, and scan time=0:05).
(iv) Two VS-ASL scans using sech and composite trains without DPC implemented into a research dm-VSI VS-ASL preparation module with optimized back-ground suppression (V_{cut}=2 cm/s using z-directed gradients, Tₛₐₜ/TI₁/TI₂=2000/1600/400 ms, 28 label-control pairs) using the GRASE readout described in (iii). An M₀ scan with ASL preparation disabled was set as the first measurement (4:29 per scan).
(v) Two VS-ASL scans using sech and composite trains with DPC using the same VS-ASL preparation module, GRASE readout, and M₀ scan as described in (iii) (4:29 per scan).

VS-ASL data processing involved pairwise label-control subtraction of the time-series data and then averaging to create a mean perfusion map. The mean perfusion map was divided by the M₀ scan to correct for variations in coil sensitivity and to generate a normalized ASL perfusion map. Of note, these perfusion maps are equivalent to relative spatial SNR maps, given the identical readouts for all VS-ASL approaches. The M₀ scan was also processed using a Brain Extraction Tool to create a brain-only mask, which was subsequently applied to the perfusion maps and DIR images.

Perfusion maps for the four VS-ASL scans were qualitatively compared with reference to the B₀ and B₁⁺ maps, paying specific attention to regions of field inhomogeneity. The brain-extracted DIR image was then used as a GM mask, given the enhanced GM contrast resulting from white matter and CSF suppression. A threshold set just above the noise floor ensured that only GM voxels were included. Using this mask on the CBF images, the GM CBF spatial coefficient of variation (spatial CoV=mean SI/SD SI), a commonly used metric to assess CBF spatial heterogeneity in ASL, was calculated.

Statistical analysis was performed on GM spatial CoV across all 5 subjects. Given the small number of subjects, a normal distribution of our GM spatial CoV data was not assumed and thus non-parametric tests that do not require assumptions about distribution were chosen. A Fried-man omnibus test was performed to evaluate the presence of a statistically significant difference in spatial CoV among the four VS-ASL methods (at p<0.05), followed by post hoc Nemenyi tests for multiple comparisons to evaluate for significant differences between each pair of VS-ASL methods (at p-adj<0.05).

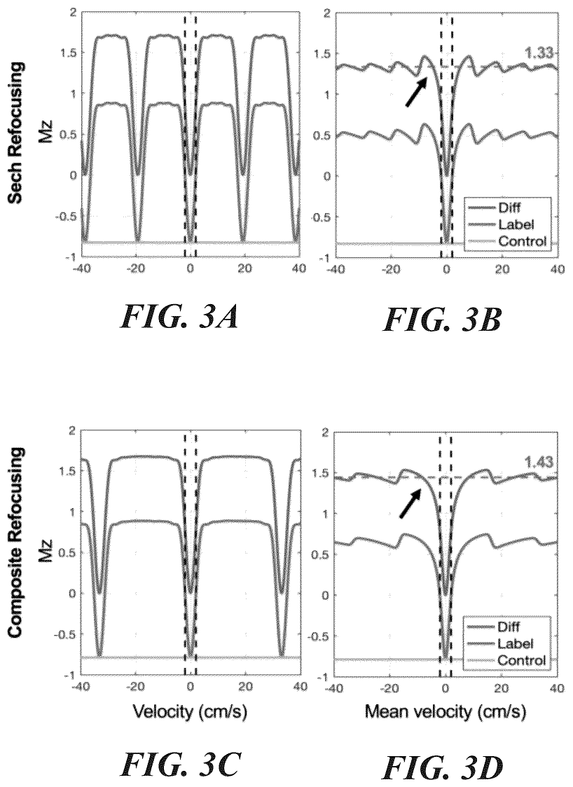

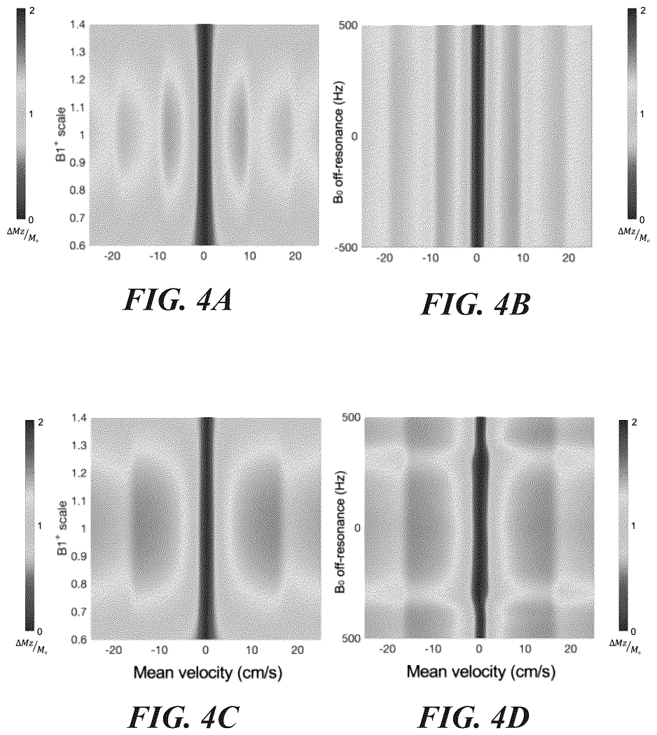

FIGS. 3A-D show example velocity responses for the sech and composite (reference) refocusing trains (i.e., FIGS. 1A and 1B, respectively). The line plots shown in FIGS. 3A-D depict velocity profiles under uniform and laminar (physiologic) flow conditions in the absence of field inhomogeneities. It can be seen from FIGS. 3A-D that the Nyquist replica interval decreases with the sech train relative to the composite under uniform flow conditions (FIGS. 3A and 3C), but the response under laminar flow conditions is quite similar (FIGS. 3B and 3D). In addition, the velocity profile near V_{cut} is sharper with the sech approach relative to the composite (FIGS. 3B and 3D, arrows), with only a 7% loss in labeling efficiency as illustrated in FIGS. 3B and 3F using number label (top-right) and dashed line (0.67 for the sech refocusing train compared with 0.72 for the composite refocusing train). The color maps of FIGS. 4A-D depict the laminar flow velocity profiles for both trains in the presence of B₁⁺ and B₀ inhomogeneity. Both trains maintain the velocity response over a large B₀/B₁⁺ range (FIGS. 4A and 4D), specifically noting perfect B₀ immunity for the sech refocusing train (FIG. 4B).

Bloch simulations incorporating T₁/T₂ relaxation were performed using publicly available software to evaluate the performance of both trains in terms of (i) magnetization (M_{z}) profile as a function of velocity (i.e., velocity response) under assumptions of both non-laminar (uniform) and laminar (physiologic) flow in the absence of field inhomogeneity, (ii) laminar flow velocity response across a wide B₀/B₁⁺ range, (iii) subtraction fidelity across a wide B₀/B₁⁺ range with and without phase cycling (DC bias), and (iv) subtraction fidelity as a function of position and B₁⁺ with and without phase cycling (stripe artifact). Both (iii) and (iv) were performed at zero velocity to specifically analyze static tissue effects.

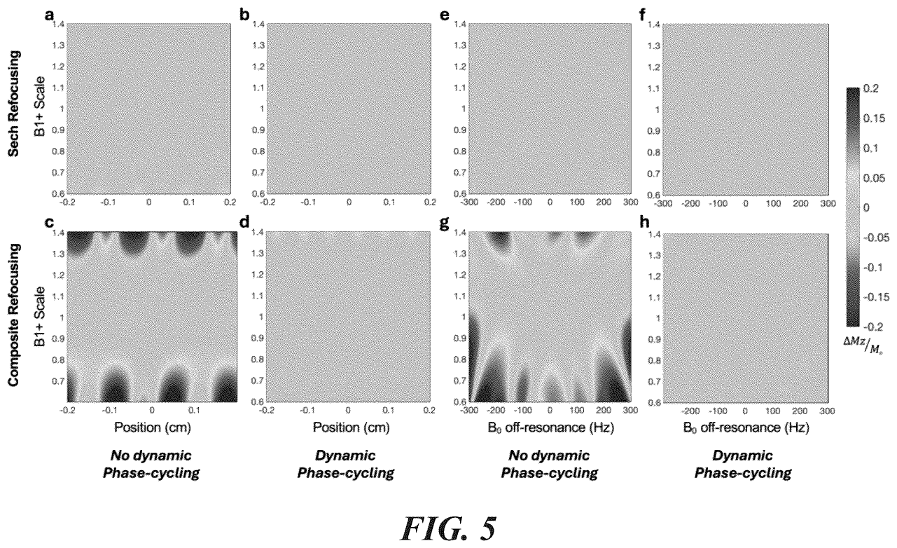

FIG. 5 shows normalized magnetization difference after subtraction (ΔM/M₀) following simulation of both composite and sech trains as a function of (i) position and B₁⁺ (stripe artifact) (FIGS. 5A-D) and (ii) off-resonance and B₁⁺ (DC bias) (FIGS. 5E-H), with and without DPC. The sech refocusing train nearly eliminates contributions from unwanted static spins in the absence of DPC, which are significant with the composite non-DPC approach. DPC completely eliminates static spin contributions for the sech approach and nearly eliminates them for the composite approach.

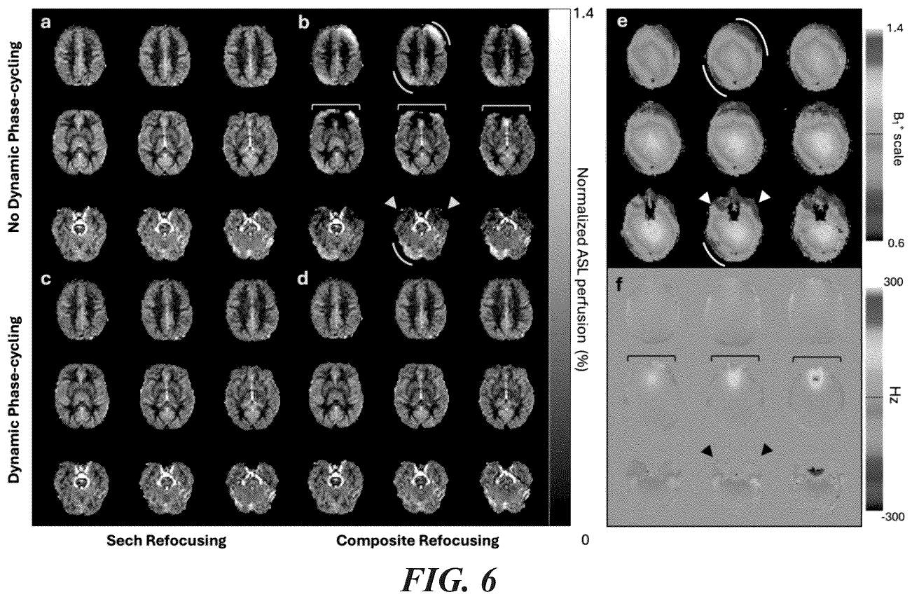

FIGS. 6A-D show normalized ASL perfusion maps for a representative subject for all four VS-ASL scan types (i.e., sech versus composite, with and without DPC). These maps also serve as relative spatial SNR maps, given the identical readouts and number of repetitions. Corresponding B₀ and B₁⁺ field maps are shown in FIGS. 6E and 6F. FIG. 6B shows marked artifacts seen with the reference approach when DPC is not used, corresponding to areas of B₀/B₁⁺ inhomogeneity. Curved braces in the top and bottom row of FIG. 6B show areas of asymmetrically increased signal in the left anterior and right posterior regions that persist through most slices and correspond to regions of B₁⁺ inhomogeneity as shown in FIG. 6E. Straight braces in the middle row of FIG. 6B show signal dropout in the anterior frontal lobes that correspond to regions of B₀ inhomogeneity as shown in FIG. 6F. In FIG. 6B, arrowheads in the bottom row show signal dropout in the anterior temporal lobes due to B₀ and/or B₁⁺ inhomogeneity as shown in FIGS. 6E-F. The three other approaches essentially eliminate these artifacts.

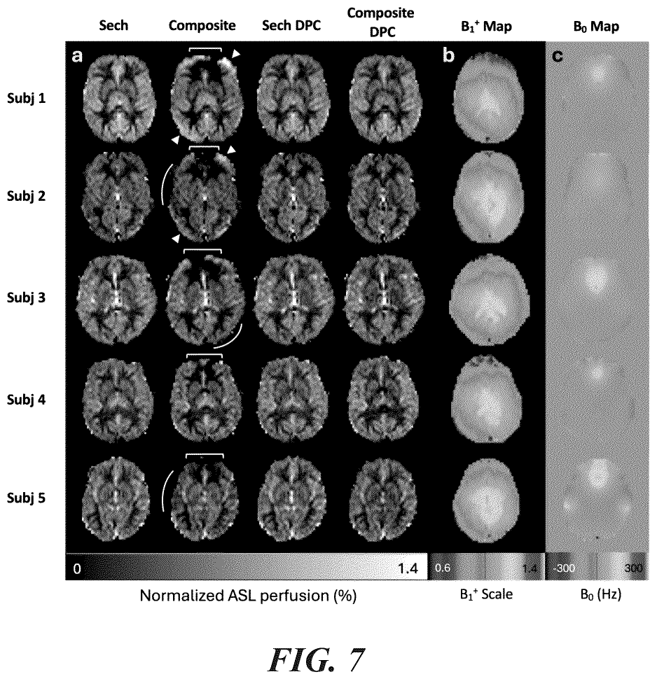

FIG. 7A shows normalized ASL perfusion maps of a single slice for the four VS-ASL methods across all 5 subjects. Associated B₀/B₁⁺ maps are shown in FIGS. 7B-C. Again seen are both marked and subtle artifacts with the non-dynamic phase cycling composite approach (white annotations), which are eliminated using the other three methods.

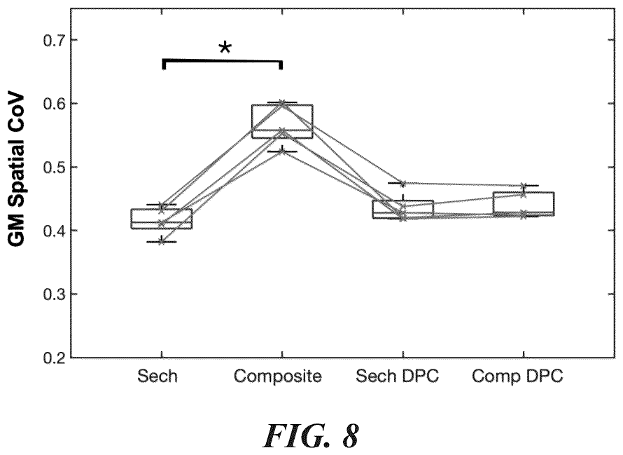

FIG. 8 shows box plots summarizing GM spatial CoV data (lower values indicate less heterogeneity) for the four approaches across all 5 subjects. Spatial CoV (i.e., perfusion heterogeneity) is statistically lower for the non-DPC sech refocusing approach compared with the non-DPC composite refocusing approach, due to the marked artifact reduction (p-adj<0.05, indicated by asterisk). Both DPC approaches also show reduced spatial CoV relative to the non-DPC composite, although not statistically significant, presumably due to the small number of subjects.

Results from the example study discussed above demonstrate that the VSI pulse train for VS-ASL, which uses adiabatic (sech) refocusing with MLEV-8 phase cycling to mitigate B₀/B₁⁺ sensitivity when using a VIC, successfully improves subtraction fidelity and reduces artifacts and signal loss in cerebral perfusion imaging in subjects. These results are corroborated by both simulation and phantom data. The disclosed approach is demonstrated to work for a single label-control subtraction pair and does not require dynamic phase cycling over four label-control pairs, which is necessary for a similar level of artifact reduction with the standard composite refocusing approach when using a VIC. Sech refocusing as described in this patent document may thus be a better choice for dual-module VSI-VS-ASL, particularly when using a single subtraction with a VIC.

In some implementations, adiabatic (sech) refocusing pulse trains based on the disclosed technology eliminate the need for DPC. Eliminating the need for DPC is advantageous for several reasons. First, a perfusion map can be generated with single label-control subtraction, permitting perfusion-based fMRI with a temporal resolution of 2*TR (as standard ASL approaches). In contrast, DPC averages four dynamic phases to create a single perfusion image at an effective temporal resolution of 8*TR, which is prohibitively low for fMRI and certain VSA-SL pulsatility methods. Furthermore, there is increased susceptibility to physiologic and bulk motion effects that can introduce artifacts and lower SNR of the averaged image. Standard data-censoring methods to remove corrupt data are also less effective, as they must be applied to each dynamic phase series independently, reducing efficacy for identifying outliers given the small number of volumes in each dynamic (¼ of the total). Additionally, using a VCC instead of a VIC can reduce the need for DPC, as the former inherently reduces static tissue subtraction error, although not as robustly as VIC with DPC. The VCC approach has the added benefit of reducing mismatch in diffusion attenuation between the label and control, which can be particularly beneficial when using velocity-selective approaches for blood volume measurements. Drawbacks of the VCC approach include substantially degraded VS profiles and labeling efficiency, which are exacerbated in the presence of B₀/B₁⁺ inhomogeneity, as well as increased sensitivity to eddy current effects. These can manifest as artifacts in CBF imaging, including B₁-dependent perfusion deficits. Conversely, the VIC approach with DPC has been demonstrated elsewhere to preserve robustness of both the velocity and static tissue responses across a wide B₀/B₁⁺ range. As such, the examples study focused on achieving similar performance with VIC, but without the DPC requirement. In principle, FT-VSI using a VCC should also benefit from adiabatic refocusing and may be explored in future studies.

Despite the increased length of the adiabatic magnetic pulse (FIG. 1A) relative to the composite (FIG. 1B) (i.e., 3.142 vs. 1 ms), the VSI train was shortened to 47 ms (from the reference 65 ms) by reducing the number of refocusing pairs from eight to four. Although this decreases the spacing of the Nyquist replicas of the sech velocity profile under non-laminar-flow conditions (FIGS. 3A and 3C), the laminar-flow velocity profile remains similar in morphology compared with the composite (FIGS. 3B and 3D). In actuality, the sech laminar-flow velocity profile provides a slightly sharper ASL bolus near the velocity cutoff. Although the sech refocusing approach has a 7% lower simulated labeling efficiency (in the absence of B₀/B₁⁺ inhomogeneity), this did not manifest empirically in the example study.

The simulated velocity response with the sech refocusing train is essentially immune to B₀ off-resonance (FIG. 4B) and performs well across a broad B₁⁺ range (FIG. 4A). In terms of static tissue subtraction, the train performs exceptionally well once the adiabatic threshold is reached in terms of both stripe artifact (FIG. 5A) and DC bias (FIG. 5E), outperforming the composite approach without DPC, whose subtractions have large artifacts (FIGS. 5C and 5G).

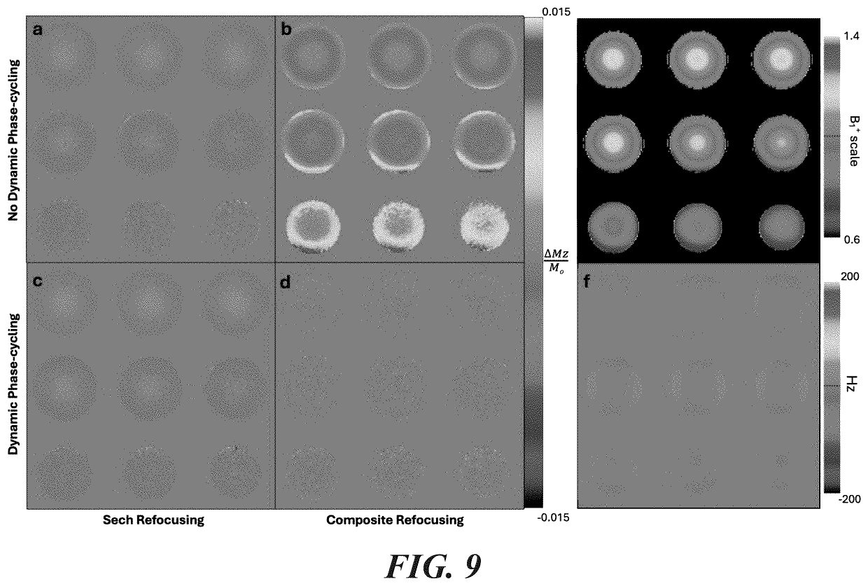

Subtraction fidelity in phantoms was also dramatically improved in the study with non-DPC sech versus non-DPC composite refocusing. Agarose phantom label-control difference images for sech trains and reference scans, with and without DPC are shown in FIG. 9A-D. Corresponding B₀ and B₁⁺ field maps are shown in FIGS. 9E-F. A small residual error with the sech train is seen to localize to central areas of increased B₁⁺ as shown in FIG. 9, suggesting subtle sensitivity to high B₁⁺ in this region (despite simulation results reporting otherwise). Interestingly, this error is only slightly mitigated by DPC. Etiology of this finding is unclear and under investigation, although it may be related to nonideal behavior of the adiabatic pulse (independent of dynamic phase) near the maximum RF transmitter voltage. In FIG. 9B, signal from static spins can be seen to significantly contaminate the composite subtraction map in the absence of DPC (RMS percentage signal difference over the whole volume=0.274%), whereas the sech train difference images of FIGS. 9A and 9C have minimal subtraction errors that appear to correspond to areas of high B₁⁺ centrally (RMS % diff over the whole volume=0.071% for sech without DPC and 0.065% for sech with DPC). As shown in FIG. 9D, the composite approach with DPC reduces subtraction error even further (RMS % diff over the whole volume=0.049%).

Dramatic artifact reduction with the non-DPC sech approach relative to the non-DPC composite approach was seen consistently in all subjects studied. Improvement corresponded to areas of both B₀ and B₁⁺ inhomogeneity (FIGS. 6-7) and was corroborated by quantitative analysis of perfusion heterogeneity via a statistically lower spatial CoV.

In the example study, the performance between the original composite and modified adiabatic trains in dual-module FT-VSI (dm-VSI) VS-ASL was compared. dm-VSI has become a highly promising VS-ASL variant poised for clinical translation due its higher temporal SNR (achieved by using two VSI modules with inherent background suppression), robustness to CSF artifacts, insensitivity to transit delays and labeling plane prescription, and intrinsic background suppression. However, dm-VSI is especially prone to subtraction errors related to B₀/B₁⁺ inhomogeneity given the short, few hundred millisecond delay between the second VSI pulse and readout. Because dm-VSI places a second VS module 300-400 ms from the readout for optimal background suppression, subtraction errors related to B₀/B₁⁺ inhomogeneity are exacerbated due to less T₁ decay between the second VSI module and acquisition, compared with single-module VSI (with 1400 ms between VSI and the recommended VS-ASL readout). Sech refocusing techniques, as disclosed in this patent document, are therefore particularly well-suited for dm-VSI implementations. In the example study, a hyperbolic secant pulse was chosen due to familiarity with sech pulse trains for ASL and empirical findings of excellent adiabaticity even after variable-rate selective excitation transformation. However, other adiabatic pulses can also be used for refocusing in VSI trains; for example, hyperbolic tangent pulses can be made very short and may also be effective for robust refocusing in the presence of nonuniform B₀/B₁⁺.

To summarize, the purpose of the example study was to mitigate the B₀/B₁⁺ sensitivity of VSI pulse trains for VS-ASL by implementing an adiabatic refocusing approach as disclosed in the present patent document. This approach aims to achieve artifact-free VSI-based per-fusion imaging through single-pair label-control subtractions, reducing the need for the currently required four-pair DPC technique when using a velocity-insensitive control. To achieve this aim, an FT-VSI train that incorporates sinc-modulated hard excitation pulses with MLEV-8-modulated adiabatic hyperbolic secant refocusing pairs was introduced. Performances between this train and the standard composite refocusing train, including with and without DPC, for dual-module VSI VS-ASL were compared. Several parameters were evaluated including: (1) simulated velocity-selective magnetization profiles and subtraction fidelity across a broad B₀/B₁⁺ field range, (2) subtraction fidelity in phantoms, and (3) image quality, artifact presence, and gray-matter perfusion heterogeneity (as measured by the spatial coefficient of variation [CoV]) in healthy human subjects. Results from the example study, as discussed above, demonstrate that the disclosed adiabatic refocusing approach significantly improves FT-VSI robustness to B₀/B₁⁺ inhomogeneity for a single label-control subtraction. Additionally, subtraction fidelity is dramatically improved in both simulation and phantoms compared with composite refocusing without DPC, and is similar compared with DPC methods. In humans, marked artifacts seen with the non-DPC composite refocusing approach are eliminated, corroborated by significantly reduced gray-matter heterogeneity (via lower spatial coefficient of variation values). It can be concluded from the above study that the VS-ASL labeling train using adiabatic refocusing pulses for VSI can reduce artifacts related to B₀/B₁⁺ inhomogeneity, thereby providing an alternative to DPC and its associated limitations, which include increased vulnerability to physiological noise and motion, reduced functional MRI applicability, and suboptimal data censoring.

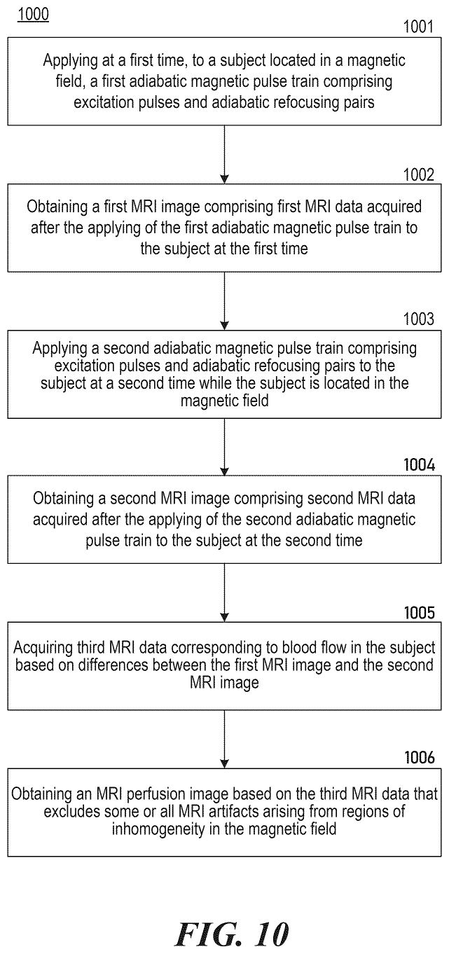

FIG. 10 shows a flow diagram illustrating an example of a method 1000 for magnetic resonance imaging based on the disclosed technology. The method 1000 includes, at 1001, applying at a first time, to a subject located in a magnetic field, a first adiabatic magnetic pulse train comprising excitation pulses and adiabatic refocusing pairs. The method 1000 includes, at 1002, obtaining a first MRI image comprising first MRI data acquired after the applying of the first adiabatic magnetic pulse train to the subject at the first time. The method 1000 includes, at 1003, applying a second adiabatic magnetic pulse train comprising excitation pulses and adiabatic refocusing pairs to the subject at a second time while the subject is located in the magnetic field. The method 1000 includes, at 1004, obtaining a second MRI image comprising second MRI data acquired after the applying of the second adiabatic magnetic pulse train to the subject at the second time. The method 1000 includes, at 1005, acquiring third MRI data corresponding to blood flow in the subject based on differences between the first MRI image and the second MRI image. The method 1000 includes, at 1006, obtaining an MRI perfusion image based on the third MRI data that excludes some or all MRI artifacts arising from regions of inhomogeneity in the magnetic field. In some implementations of the method 1000, at least one of the first adiabatic magnetic pulse train or the second adiabatic magnetic pulse train further comprises gradient pulses. In some implementations of the method 1000, at least one of the first MRI image or the second MRI image is obtained in-part based on selective interaction of the first adiabatic magnetic pulse train or the second adiabatic magnetic pulse train with spins in arterial blood water of the subject based on a velocity of the arterial blood water being at or above a predetermined threshold velocity.

Various operations disclosed herein can be implemented using a processor/controller configured to include, or be coupled to, a memory that stores processor executable code that causes the processor/controller carry out various computations and processing of information. The processor/controller can further generate and transmit/receive suitable information to/from the various system components, as well as suitable input/output (IO) capabilities (e.g., wired or wireless) to transmit and receive commands and/or data. The processor/controller may, for example, provide signals to control the operation of various components such as light sources and detectors that are disclosed herein. The processor/controller may be further configured to perform various method steps and computations that are disclosed in this patent document.

Some of the embodiments described herein are described in the general context of methods or processes, which may be implemented in one embodiment by a computer program product, embodied in a computer-readable medium, including computer-executable instructions, such as program code, executed by computers in networked environments. A computer-readable medium may include removable and non-removable storage devices including, but not limited to, Read Only Memory (ROM), Random Access Memory (RAM), compact discs (CDs), digital versatile discs (DVD), etc. Therefore, the computer-readable media can include a non-transitory storage media. Generally, program modules may include routines, programs, objects, components, data structures, etc. that perform particular tasks or implement particular abstract data types. Computer- or processor-executable instructions, associated data structures, and program modules represent examples of program code for executing steps of the methods disclosed herein. The particular sequence of such executable instructions or associated data structures represents examples of corresponding acts for implementing the functions described in such steps or processes.

Some of the disclosed embodiments can be implemented as devices or modules using hardware circuits, software, or combinations thereof. For example, a hardware circuit implementation can include discrete analog and/or digital components that are, for example, integrated as part of a printed circuit board. Alternatively, or additionally, the disclosed components or modules can be implemented as an Application Specific Integrated Circuit (ASIC) and/or as a Field Programmable Gate Array (FPGA) device. Some implementations may additionally or alternatively include a digital signal processor (DSP) that is a specialized microprocessor with an architecture optimized for the operational needs of digital signal processing associated with the disclosed functionalities of this application. Similarly, the various components or sub-components within each module may be implemented in software, hardware or firmware. The connectivity between the modules and/or components within the modules may be provided using any one of the connectivity methods and media that is known in the art, including, but not limited to, communications over the Internet, wired, or wireless networks using the appropriate protocols.

While this document contains many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few implementations and examples are described and other implementations, enhancements and variations can be made based on what is described and illustrated in this patent document.

What is claimed:

1. A method for magnetic resonance imaging (MRI), comprising:
applying at a first time, to a subject located in a magnetic field, a first adiabatic magnetic pulse train comprising excitation pulses and adiabatic refocusing pairs;
obtaining a first MRI image comprising first MRI data acquired after the applying of the first adiabatic magnetic pulse train to the subject at the first time;
applying a second adiabatic magnetic pulse train comprising excitation pulses and adiabatic refocusing pairs to the subject at a second time while the subject is located in the magnetic field;
obtaining a second MRI image comprising second MRI data acquired after the applying of the second adiabatic magnetic pulse train to the subject at the second time;
acquiring third MRI data corresponding to blood flow in the subject based on differences between the first MRI image and the second MRI image; and
obtaining an MRI perfusion image based on the third MRI data that excludes some or all MRI artifacts arising from regions of inhomogeneity in the magnetic field,
wherein at least one of the first adiabatic magnetic pulse train or the second adiabatic magnetic pulse train further comprises gradient pulses,
wherein at least one of the first MRI image or the second MRI image is obtained in-part based on selective interaction of the first adiabatic magnetic pulse train or the second adiabatic magnetic pulse train with spins in arterial blood water of the subject based on a velocity of the arterial blood water being at or above a predetermined threshold velocity.

2. The method of claim 1, wherein the adiabatic refocusing pairs are hyperbolic secant adiabatic refocusing pairs, wherein the excitation pulses are interleaved with the adiabatic refocusing pairs.

3. The method of claim 1, wherein the excitation pulses are modulated by a waveform.

4. The method of claim 2, wherein the adiabatic refocusing pairs are modulated by phase cycling.

5. The method of claim 1, wherein the first adiabatic magnetic pulse train and the second adiabatic magnetic pulse train each comprises a predetermined number of the adiabatic refocusing pairs, wherein the predetermined number is selected such that a length of the first adiabatic magnetic pulse train and the second adiabatic magnetic pulse train, respectively, is minimized.

6. The method of claim 1, wherein the MRI perfusion image describes blood flow through a brain of the subject.

7. The method of claim 1, wherein the MRI artifacts include artifacts arising from static (B₀) and transmit (B₁⁺) magnetic field inhomogeneities.

8. The method of claim 7, further comprising:
obtaining one or more maps indicating the static (B₀) and transmit (B₁⁺) magnetic field inhomogeneities; and
determining an accuracy of the MRI perfusion image by correlating locations in the MRI perfusion image to the static (B₀) and transmit (B₁⁺) magnetic field inhomogeneities indicated on the one or more maps.

9. The method of claim 1, wherein the subject is a human or animal.

10. The method of claim 1, wherein the subject is located in an MRI scanner configured to apply the first adiabatic magnetic pulse train to the subject at the first time and apply the second adiabatic magnetic pulse train to the subject at the second time.

11. The method of claim 1, wherein the first MRI data and the second MRI data comprise time-series data, wherein obtaining the MRI perfusion image comprises averaging the time-series data.

12. A computer program product, embodied on a computer-readable medium, operable to cause a data processing apparatus to perform operations for magnetic resonance imaging (MRI) comprising:
applying at a first time, to a subject located in a magnetic field, a first adiabatic magnetic pulse train comprising excitation pulses and adiabatic refocusing pairs;
obtaining a first MRI image comprising first MRI data acquired after the applying of the first adiabatic magnetic pulse train to the subject at the first time;
applying a second adiabatic magnetic pulse train comprising excitation pulses and adiabatic refocusing pairs to the subject at a second time while the subject is located in the magnetic field;
obtaining a second MRI image comprising second MRI data acquired after the applying of the second adiabatic magnetic pulse train to the subject at the second time;
acquiring third MRI data corresponding to blood flow in the subject based on differences between the first MRI image and the second MRI image; and
obtaining an MRI perfusion image based on the third MRI data that excludes some or all MRI artifacts arising from regions of inhomogeneity in the magnetic field,
wherein at least one of the first adiabatic magnetic pulse train or the second adiabatic magnetic pulse train further comprises gradient pulses,
wherein at least one of the first MRI image or the second MRI image is obtained in-part based on selective interaction of the first adiabatic magnetic pulse train or the second adiabatic magnetic pulse train with spins in arterial blood water of the subject based on a velocity of the arterial blood water being at or above a predetermined threshold velocity.

13. The computer program product of claim 12, wherein the excitation pulses are interleaved with hyperbolic secant refocusing pairs.

14. The computer program product of claim 12, wherein the adiabatic refocusing pairs are modulated by phase cycling.

15. The computer program product of claim 12, wherein the MRI artifacts include artifacts arising from static (B₀) and transmit (B₁⁺) magnetic field inhomogeneities.

16. A magnetic resonance imaging (MRI) system, comprising:
a radio frequency (RF) subsystem configured to:
apply at a first time, to a subject located in a magnetic field, a first adiabatic magnetic pulse train comprising excitation pulses and adiabatic refocusing pairs, and
apply at a second time, to the subject while located in the magnetic field, a second adiabatic magnetic pulse train comprising excitation pulses and adiabatic refocusing pairs; and
a processor and a computer-readable medium with instructions stored thereon, wherein the instructions upon execution by the processor cause the processor to:
obtain a first MRI image comprising first MRI data acquired after the applying of the first adiabatic magnetic pulse train to the subject at the first time;
obtain a second MRI image comprising second MRI data acquired after the applying of the second adiabatic magnetic pulse train to the subject at the second time;
acquire third MRI data corresponding to blood flow in the subject based on differences between the first MRI image and the second MRI image; and
obtain an MRI perfusion image based on the third MRI data that excludes some or all MRI artifacts arising from regions of inhomogeneity in the magnetic field,
wherein at least one of the first adiabatic magnetic pulse train or the second adiabatic magnetic pulse train further comprises gradient pulses,
wherein at least one of the first MRI image or the second MRI image is obtained in-part based on selective interaction of the first adiabatic magnetic pulse train or the second adiabatic magnetic pulse train with spins in arterial blood water of the subject based on a velocity of the arterial blood water being at or above a predetermined threshold velocity.

17. The magnetic resonance imaging system of claim 16, wherein the adiabatic refocusing pairs are hyperbolic secant adiabatic refocusing pairs, wherein the excitation pulses are interleaved with the adiabatic refocusing pairs.

18. The magnetic resonance imaging system of claim 16, wherein the excitation pulses are modulated by a waveform.

19. The magnetic resonance imaging system of claim 16, wherein the first adiabatic magnetic pulse train and the second adiabatic magnetic pulse train each comprises a predetermined number of the adiabatic refocusing pairs, wherein the predetermined number is selected such that a length of the first adiabatic magnetic pulse train and the second adiabatic magnetic pulse train, respectively, is minimized.

20. The magnetic resonance imaging system of claim 16, wherein the MRI artifacts include artifacts arising from static (B₀) and transmit (B₁⁺) magnetic field inhomogeneities.
